(19) United States
(12) Patent Application Publication
(10) Pub. No.: US 2025/0277856 A1
(43) Pub. Date: Sep. 4, 2025

(54) SYSTEM AND METHOD FOR ACCURATELY DETERMINING ENERGY DEVICE STATE-OF-CHARGE AND STATE-OF-HEALTH WITH THE ADDITION OF CONFIDENCE SCORING

(71) Applicant: NGENX LLC, Las Vegas, NV (US)

(72) Inventors: Xueying Li, Seattle, WA (US); David Shock, Bainbridge Island, WA (US); Daniel Shaw, Seattle, WA (US); Yujia Liang, Bellevue, WA (US)

(21) Appl. No.: 19/065,982

(22) Filed: Feb. 27, 2025

Related U.S. Application Data
(60) Provisional application No. 63/559,686, filed on Feb. 29, 2024.

(51) Int. Cl. G01R 31/367; G01R 31/36; G01R 31/387; G01R 31/392

(52) U.S. Cl. CPC G01R 31/367; G01R 31/3648; G01R 31/387; G01R 31/392

(57) ABSTRACT

Methods and systems are provided for using a predictive model to monitor batteries and other energy devices. In some examples, the predictive model may receive, as input, data indicating one or more parameters of a battery system. In such examples, the predictive model may generate, as output, one or more corrections or updates to the one or more parameters. In certain examples, the one or more parameters may include a state-of-charge of the battery system and/or a state-of-health of the battery system. In certain examples, the one or more corrections or updates may include a confidence score corresponding to an accuracy of the state-of-charge and/or an accuracy of the state-of-health. In some examples, the one or more corrections or updates may be updated, according to one or more outputs of the predictive model, responsive to one or more convergence criteria not being met.

### CROSS-REFERENCE TO RELATED APPLICATION

The present application claims priority to U.S. Provisional Application No. 63/559,686, entitled “SYSTEM AND METHOD FOR ACCURATELY DETERMINING OF ENERGY DEVICE STATE-OF-CHARGE AND STATE-OF-HEALTH WITH THE ADDITION OF CONFIDENCE SCORING” and filed on Feb. 29, 2024. The entire contents of the above-identified application are hereby incorporated by reference for all purposes.

### FIELD

Embodiments of the subject matter disclosed herein relate to systems and methods for batteries, and more particularly to battery management systems for using confidence scoring to determine state of charge (SOC) and/or state of health (SOH).

### BACKGROUND

Battery management systems and methods for determining the state of charge (SOC) and the state of health (SOH) of a single cell or a battery pack are limited by insufficient accuracy. For example, the SOC or the SOH as estimated by such systems and methods may be different from the real world values due to cells undergoing different environmental conditions or different usage scenarios. Having an accurate system applicable across all batteries from different manufacturers is extremely challenging.

### BRIEF DESCRIPTION OF THE DRAWINGS

FIG. 1 shows an example block diagram of battery monitoring system, including a predictive model, in accordance with at least one embodiment;

FIG. 2 shows an example process flow diagram of a predictive model implementing a recursive algorithm, in accordance with at least one embodiment;

FIG. 3 shows an example process flow diagram of a recursive algorithm, in accordance with at least one embodiment;

FIG. 4 shows an example process flow diagram for processing matrices of battery parameters, in accordance with at least one embodiment;

FIG. 5 shows example plots of feature extraction for electrochemical impedance spectra, in accordance with at least one embodiment;

FIG. 6 shows example plots of feature correlation and principal component analysis (PCA), in accordance with at least one embodiment;

FIG. 7 shows an example schematic cross-sectional diagram of an as-built cell, in accordance with at least one embodiment; and

FIG. 8 shows an example process flow diagram of a method for using a predictive model to monitor a battery system, in accordance with at least one embodiment.

### DETAILED DESCRIPTION

Techniques described and suggested herein include at least one embodiment of a method, including: retrieving: baseline data of a battery system, indicating a battery chemistry of the battery system and a battery type of the battery system; real-time data of the battery system, indicating an electrochemical performance of the battery system; a state-of-charge, measured for the battery system; and a state-of-health, measured for the battery system; identifying a set of battery parameters based, at least in part, on the baseline data and the real-time data; providing the set of battery parameters, the state-of-charge, and the state-of-health as input to a recursive algorithm; receiving, as output from the recursive algorithm, a first confidence score corresponding to an accuracy of the state-of-charge and an accuracy of the state-of-health; determining one or more corrections to correct the set of battery parameters, the state-of-charge, and the state-of-health, based, at least in part, on the first confidence score; and responsive to a convergence criterion not being met: providing the corrected set of battery parameters, the corrected state-of-charge, and the corrected state-of-health as input to the recursive algorithm; receiving, as output from the recursive algorithm, a second confidence score corresponding to an accuracy of the corrected state-of-charge and an accuracy of the corrected state-of-health; and updating the one or more corrections.

In at least one embodiment, a system includes: a controller; and non-transitory memory storing executable instructions that, if performed by the controller, causes the controller to: receive one or more metrics including a measured state-of-charge of a battery cell and/or a measured state-of-health of the battery cell; generate a feature matrix based, at least in part, on a plurality of feature parameters indicating an electrochemical performance of the battery cell; generate a chemistry matrix based, at least in part, on one or more chemistry reference tables indicating a battery chemistry of the battery cell; generate a system matrix based, at least in part, on a plurality of system parameters indicating a battery type of the battery cell; predict, via a predictive model, a confidence score based, at least in part, on the one or metrics, the feature matrix, the chemistry matrix, and the system matrix; determine a matrix correction to correct the feature matrix, the chemistry matrix, and/or the system matrix based, at least in part, on the confidence score; update the one or more metrics based, at least in part, on the confidence score; and in response to a convergence threshold and/or a maximum number of iterations not being met: predict, via the predictive model, an updated confidence score based, at least in part, on the one or more updated metrics, the corrected feature matrix, the corrected chemistry matrix, and/or the corrected system matrix; and update the one or more metrics based, at least in part, on the updated confidence score.

In at least one embodiment, a battery monitoring system includes: one or more battery cells; one or more sensors; a battery management system to adjust one or more operating parameters of the one or more battery cells, the battery management system communicably coupled to the one or more sensors; and one or more controllers storing executable instructions in non-transitory memory that, if performed by the one or more controllers, are to cause the one or more controllers to: provide, as input to a predictive model, data from the one or more sensors; retrieve, as output from the predictive model: one or more predictions including a predicted state-of-charge of the one or more battery cells and/or a predicted state-of-health of the one or more battery cells; and a first score indicating a confidence level of the one or more predictions; transmit, to the predictive model, the one or more predictions and the first score; receive, from the predictive model, an indication to update the one or more predictions; retrieve, as output from the predictive model: one or more updates based, at least in part, on the first score, the one or more updates including an updated state-of-charge of the one or more battery cells and/or an updated state-of-health of the one or more battery cells; a second score indicating a confidence level of the one or more updates; transmit, to the predictive model, the one or more updates and the second score; receive, from the predictive model, an indication that the one or more updates are accurate; and transmit, to the battery management system, the one or more updates.

These, as well as other aspects, advantages, and alternatives will become apparent to those of ordinary skill in the art by reading the following detailed description, with reference where appropriate to the accompanying drawings. Further, it should be understood that descriptions and figures provided herein are intended to illustrate the invention by way of example only and, as such, that numerous variations are possible.

For example, the following description relates to various embodiments of systems and methods to determine state of charge (SOC) and state of health (SOH) using confidence scoring. In certain embodiments, a predictive model that implements a recursive algorithm may generate a confidence score. To generate the confidence score, the recursive algorithm may receive a measured SOC and a measured SOH, as well as one or more parameters indicative of a battery system or type, a battery chemistry, or other features of a battery. The recursive algorithm may use the confidence score to correct or otherwise update the measured SOC, the measured SOH, and/or the one or more parameters. In this way, accuracy of measured SOC and/or measured SOH may be improved based, at least in part, on parameters specific to a given battery for which the SOC and/or the SOH is measured.

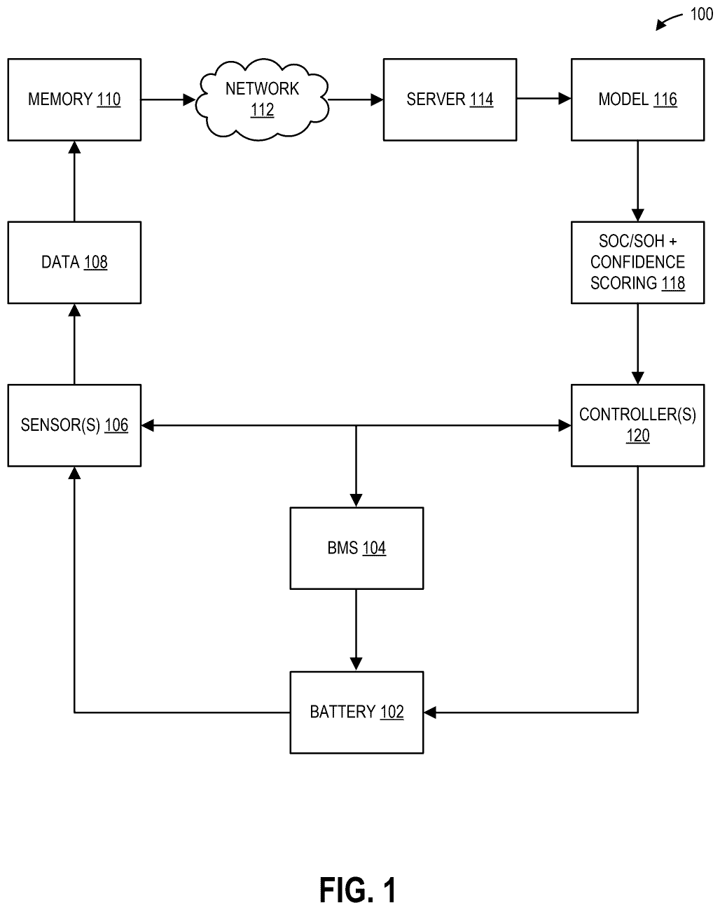

As shown in the example of FIG. 1, a battery monitoring system 100 in an embodiment can use elements such as one or more electrical and/or physical sensors 106 to collect data 108 from a battery 102 (also referred to herein as an energy device 102 or an energy storage device 102), as well as a surrounding environment, and store the data 108 in elements such as memory 110 (e.g., a non-transitory computer-readable storage medium, or the like). In certain embodiments, the data 108 can be uploaded to a storage device (e.g., a non-transitory computer-readable storage medium, or the like), at a server 114 as an example, through a network 112 (e.g., a wireless network). In an exemplary embodiment, the data 108 can be processed through a predictive model 116 (e.g., stored on the server 114 and/or in the memory 110) to determine SOH and/or SOC with confidence scoring 118. The determined SOH and/or SOC with confidence scoring 118 can be reported back to a battery management system 104 for the battery 102 and/or fed into one or more controllers 120 that monitor the battery 102, for example.

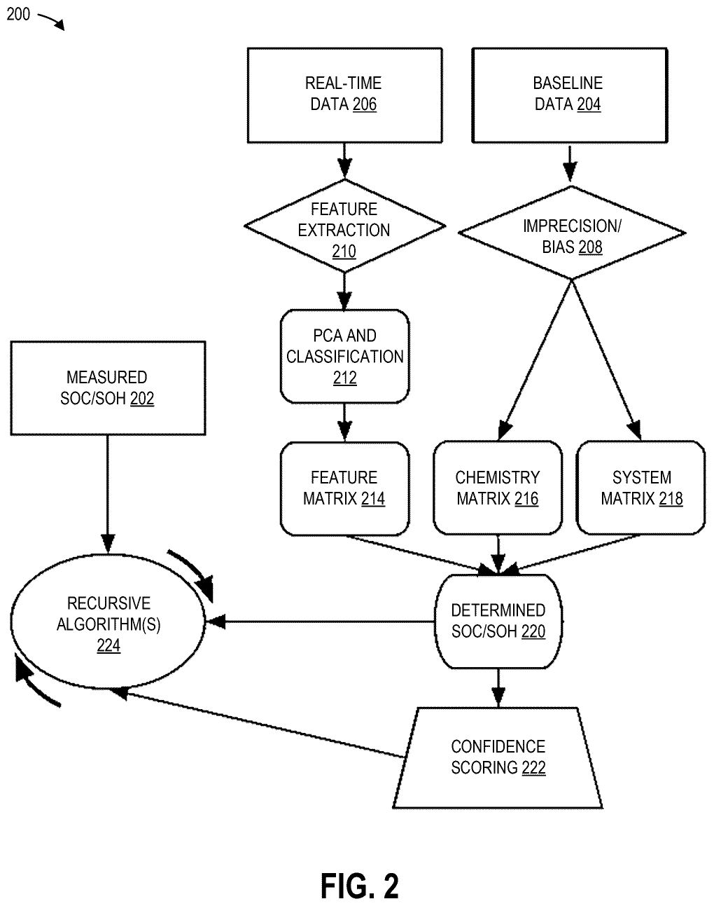

As shown in the example of FIG. 2, a method 200 in an embodiment can include extracting or otherwise identifying unique features 210 from received real-time data 206 to generate a feature matrix 214 (e.g., indicating electrochemical performance of the battery), importing or otherwise generating a chemistry matrix 216 (e.g., indicating a battery chemistry) and a system matrix 218 (e.g., indicating a system, or type, of the battery) from received baseline data 204, building and training one or more recursive algorithms 224, and determining SOH and SOC 220, using confidence scoring 222 based, at least in part, on imprecision/bias 208 identified in the baseline data 204. In at least one embodiment, confidence scoring 222 can be a criterion or indicator that shapes or otherwise adjusts a predictive model (e.g., a model implementing the recursive algorithm(s) 224, such as the predictive model 116 of FIG. 1) in some embodiments and/or can provide information to users about a comprehensive confidence level of predictions from the predictive model considering the battery chemistry and system (e.g., via chemistry and system matrices 216, 218). The method 200 in various examples can be applicable to different chemistries with its inclusion of the chemistry matrix 216. In at least one embodiment, the method 200 may be implemented in the battery monitoring system 100 of FIG. 1.

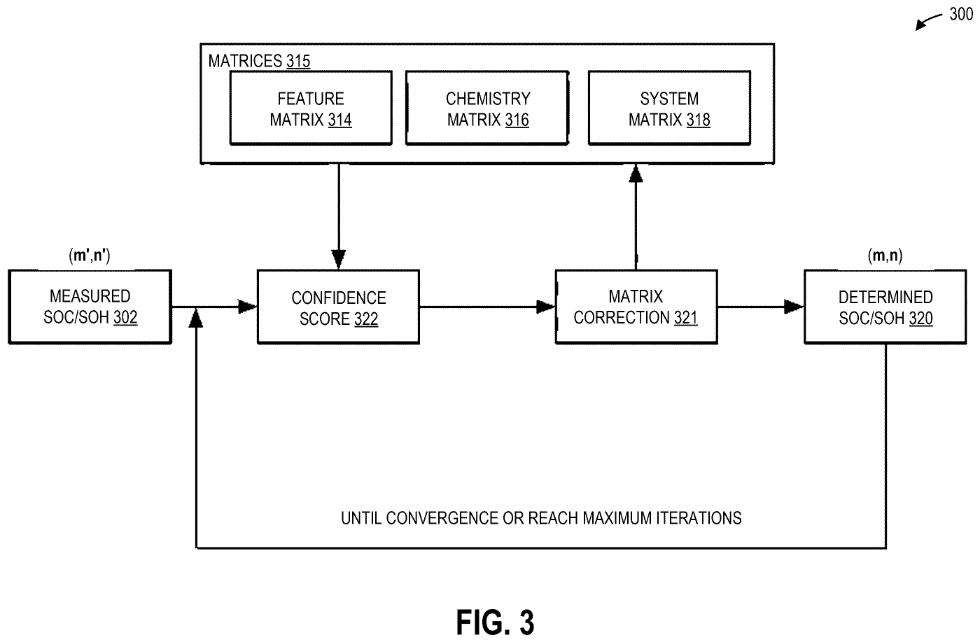

In some embodiments, the predictive model can use a supervised recursive matrices algorithm, such as the recursive algorithm(s) 224 shown in the example of FIG. 2. In some embodiments, the predictive model can apply a principal component analysis and classification 212 in reverse with a degree of influence based on matrices that are determined to be the best fit for the chemistries of a given battery or batteries to generate the feature matrix 214. Details about the recursive algorithms of some embodiments is described in detail herein with reference to FIG. 3.

As shown in the example of FIG. 3, a confidence score 322 can be generated from a predictive model (e.g., the predictive model 116 of FIG. 1) implementing a recursive algorithm 300. By using bias/imprecision from a given battery's chemistry and system, e.g., from a plurality of matrices 315 storing battery parameter values, the confidence score 322 can be improved in various embodiments beyond just statistical error from the predictive model. In some embodiments, the confidence score 322 can be used to regulate the recursive algorithm 300 when correcting 321 the matrices 315 based on measured SOC and SOH 302 and/or determined SOC and SOH 320. The bias and imprecision from the given battery's system and chemistry can be considered in the confidence scoring 322 to represent an accuracy of prediction in some examples. In return, the confidence scoring 322 can be used as feedback to regulate (the recursive algorithm 300 implemented by) the predictive model when training the datasets. In certain embodiments, the recursive algorithm 300 may be performed as part of the method 200 of FIG. 2 (e.g., substituting or supplementing one or more elements of the method 200, such as the recursive algorithm(s) 224).

Use of the recursive algorithm 300 in various embodiments can allow for modeling SOH and SOC as both predicted outputs and features fed (back) into the predictive model. In certain embodiments, the interrelationships between the SOH and the SOC can be counted (e.g., formally correlated) when extracting features by tracking each as a function of the other.

The recursive algorithm 300 in various embodiments can iterate until a convergence threshold (e.g., a maximum difference between the measured SOC and SOH 302 and the determined SOC and SOH 320) or a maximum number of iterations is reached, under the regulation of the confidence score 322.

$$[ F ( α ij , ( m , n ) ) ] \cdot [ C ( β ij , ( m , n ) ) ] \cdot [ S ( λ ij ) ] \cdot ( {m}^{′} , {n}^{′} ) = ( m , n ) \qquad ( 1 )$$

$$( {m}^{′} , {n}^{′} ) = [ F - 1 ( α ij , ( m , n ) ) ] \cdot [ C - 1 ( β ij , ( m , n ) ) ] \cdot [ S - 1 ( λ ij ) ] \cdot ( m , n ) \qquad ( 2 )$$

$$p = f ( ( m , n ) , [ C ( β ij , ( m , n ) ) ] , [ S ( λ ij ) ] ) \qquad ( 3 )$$

As shown in example equations (1)-(3): (m′,n′) can be the measured SOC and SOH 320, which can be codependent; (m,n) can be the determined (or corrected) SOC and SOH 302, which can be codependent; [F] can be a feature matrix 314 obtained from features from real-time data; [C] and [S] can be chemistry and system matrices 316, 318, respectively, of imprecision and bias in chemistry and system, respectively; αij, βij, and λij can be parameters whose values can be represented as elements of the feature, chemistry, and system matrices 314, 316, 318 during a given iteration of the recursive algorithm 300; [F−1], [C−1], and [S−1] can be inverse matrices of [F], [C], and [S]; and p, the confidence score 322, can be a function of a confidence level of the determined (or corrected) SOC and SOH 320, considering the imprecision and bias from the battery's chemistry and system (e.g., via the chemistry and system matrices 316, 318).

The method 200 in various embodiments uses a baseline dataset (e.g., the baseline data 204) for each battery chemistry/type to determine the imprecision/bias 208 and train the predictive model. Real-time data (e.g., the real-time data 206) during usage or operations of each energy device can be imported into the recursive algorithm(s) 224 to correct the feature matrix 214 and generate one or more confidence scores 222 in combination with the chemistry and system matrices 216, 218.

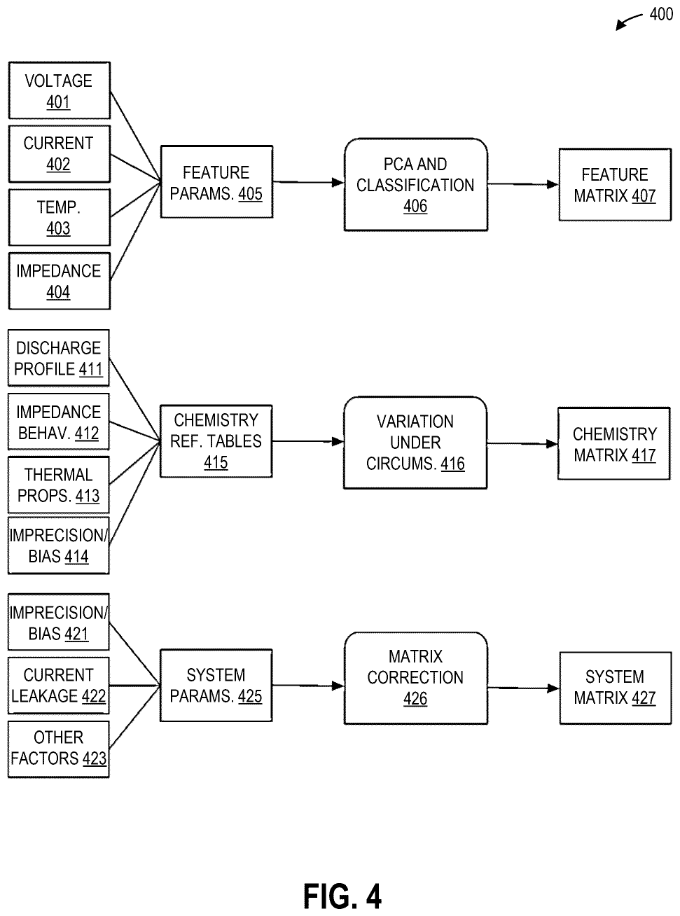

The baseline data 204 to be used by the predictive model can be built, aggregated, or otherwise retrieved in various embodiments from single cells and battery packs of different chemistries including but not limited to lithium-ion batteries, nickel metal hydride batteries, aluminum-ion batteries or other multivalent batteries (e.g., magnesium batteries, zinc batteries, etc.), and the like (e.g., other secondary batteries). A discharge profile 411, an impedance behavior 412, one or more thermal properties 413, and imprecision/bias 414 unique to each chemistry can be recorded in one or more chemistry reference tables 415 as shown in the example of FIG. 4, illustrating a method 400 of processing matrices of battery parameters to be used by a predictive model. In some embodiments, the one or more chemistry reference tables 415 can be further processed (e.g., formatted or otherwise modified) into a chemistry matrix 417 with a calculation 416 of variation of SOH and/or SOC under different circumstances unique to each chemistry. In certain embodiments, the method 400 is performed as part of the method 200 of FIG. 2 (e.g., substituting or supplementing one or more elements of the method 200).

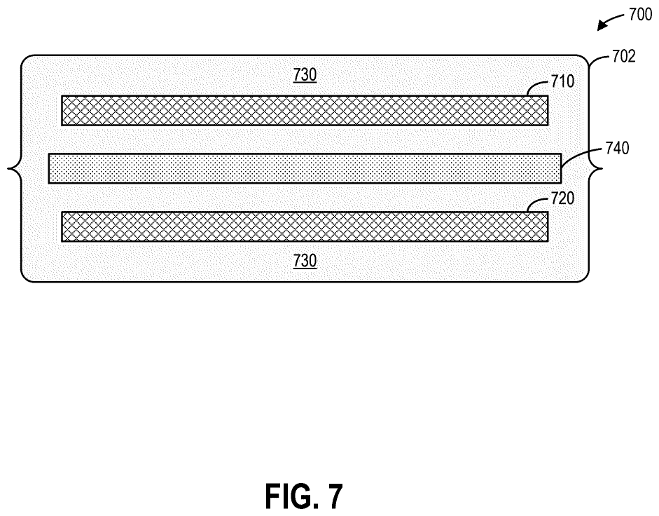

Collecting or otherwise retrieving baseline data (e.g., the baseline data 204) on energy devices can be carried out in various embodiments under different discharge conditions, rest/equilibrium time, and/or temperatures. As shown in the example of FIG. 7, an as-built cell 700 (e.g., the battery 102 of FIG. 1) in various embodiments can include a cathode 710 (e.g., including a current collector and a cathode active material layer), an anode 720 (e.g., including a current collector, such as Al foil, and an anode active material layer), an electrolyte 730, and other suitable or desirable components (e.g., a separator 740) in a casing 702. In some examples, a form factor of cells (e.g., a physical shape, size, and/or configuration of the cells) can include, but is not limited to, 18650 standard cylindrical cells, pouch cells, coin cells, or other suitable formats. In additional or alternative examples, the as-built cell 700 can be one of a plurality of cells 700 in a battery pack, connected either in series or parallel or both. In an exemplary embodiment, there can be a protection circuit or a battery management system included in the battery packs. The testing method (e.g., to determine the SOC and/or the SOH, such as the method 200) in various embodiments can be discrete, continuous, or dynamic (e.g., depending on certain conditions). For example, the cells in some examples can be tested under different discharge C rates throughout one full discharge cycle or more. The cells in at least one example can be tested in a temperature-controlled chamber at a constant temperature between 0° C. and 45° C. Thermocouples can be used in some cases (e.g., where close monitoring of temperature is desired).

The method 200 in various embodiments can implement the method 400 to utilize features, such as a plurality of feature parameters 405, extracted from voltage measurements 401, current measurements 402, temperature measurements 403, electrochemical impedance spectroscopy (EIS) measurements 404, and/or other electrical or physical measurements on energy devices such as described in the example of FIG. 4.

The method 200 in various embodiments records the measured SOC and/or SOH 202 from methods such as coulombic counting, impedance detection, and voltage detection. The measured SOC and/or SOH 202 can be used as one of the inputs to train the recursive algorithm(s) 224 in some examples.

An EIS measurement in various embodiments may be taken across a range of frequencies or at certain frequencies with specified excitation of voltage or current. An impedance captured from the EIS measurement (e.g., the EIS measurements 404) can be extracted into real and imaginary parts, which can be converted to absolute impedance and phase as well. The features (e.g., of the plurality of feature parameters 405) can be extracted from such EIS measurements with mathematical methods including but not limited to finding extremes, abrupt changes, calculating derivatives and differences, and smoothing data.

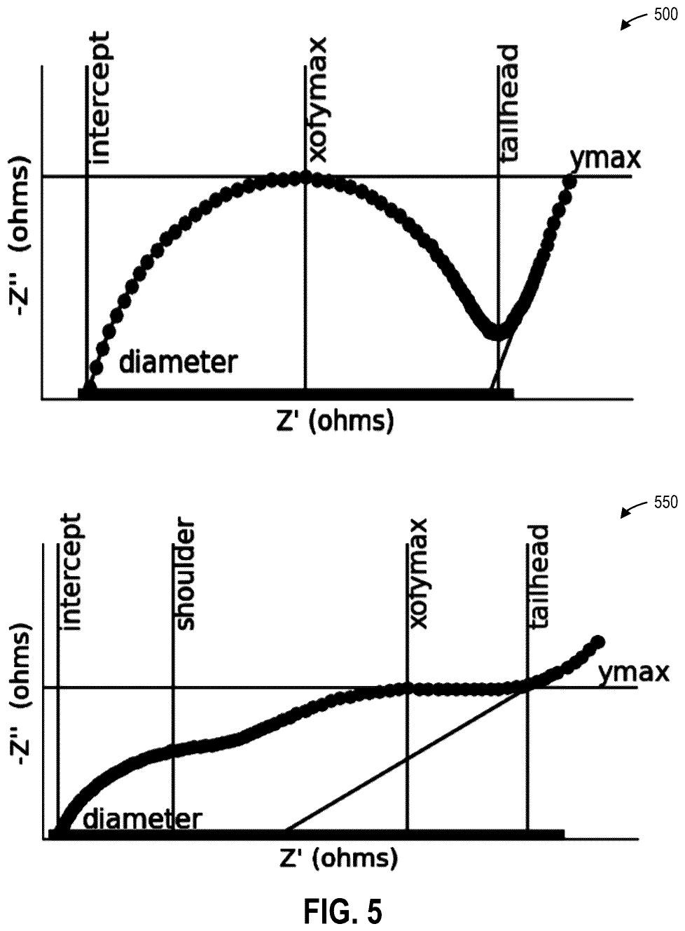

The curves in Nyquist plots 500 and 550 of imaginary impedance and real impedance, respectively, can be analyzed to extract features, as shown in the example of FIG. 5. The raw data in various examples was interpolated first. From each of the plots 500 and 550, the start of the tail (tailhead) can be obtained with smoothing and derivatives or manual input. The intercept with x-axis (intercept), the maximum in y-axis (ymax), and a corresponding x value of ymax (xofymax) can be extracted from each of the plots 500 and 550. The slope of the tail can be extracted with linear fitting on the tail in one example. The diameter of the semicircle formed by the curve in each of the plots 500 and 550 can be calculated with the distance between the intercept and center of the semicircle in one example. The center of the semicircle can be obtained by finding the center of curvature with dissection at half max and 0.75 of max in one example. In the case of more than one semicircle being formed by a curve (e.g., as in the plot 550), the connection (shoulder) between two semicircles can be found. Other features including shape, value(s) at half max, and value(s) at 0.75 of max can also be obtained from the Nyquist plots in various embodiments, even though not illustrated in the example of FIG. 5. Shape can be the ratio between the differences from each of center of 0.75 max and center of half max to intercept in one example.

Features (e.g., the plurality of feature parameters 405) from voltage (e.g., measurement 401), current (e.g., measurement 402), temperature (e.g., measurement 403), and other electrical or physical measurements (e.g., measurement 404) can be extracted with mathematical methods including but not limited to curve fitting, finding extremes, abrupt changes, calculating derivatives and differences, and/or smoothing data.

Feature extraction as shown in the example of FIG. 4 can be applicable to various chemistries including various lithium-ion batteries, aluminum-ion batteries, magnesium batteries, zinc batteries, nickel metal hydride batteries, and other suitable chemistries.

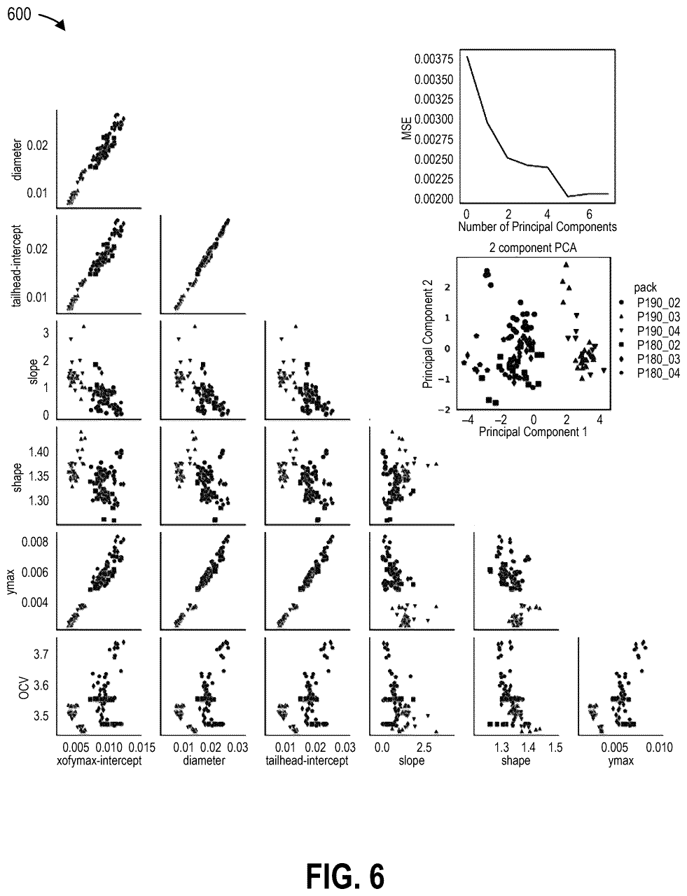

The plurality of feature parameters 405 can be further processed (e.g., formatted or otherwise modified), such as reduced by principal component analysis and classified 406, into a feature matrix 407. One such example is illustrated by a set of plots 600 as shown in the example of FIG. 6. Some features can be subtracted from, divided by, or operated upon by other features in other methods. For example, tailhead-intercept can be the difference between tailhead and intercept, xofymax-intercept can be the difference between xofymax and intercept, etc. The processed features can be checked for any existing correlation in one example. The processed features can be scaled and normalized before principal component analysis in one example. The optimal number of principal components can be determined in various embodiments through comparing the mean squared error at each number of components. The distribution of principal components can be used in various embodiments in classification, regression, or other analyses.

The predictive model in various embodiments can be established based on the understanding of bias and imprecision originating from two primary sources: system/hardware and chemistry. The predictive model in some examples can use the chemistry-level imprecision/bias 414 (e.g., unique to a battery chemistry) to define confidence intervals around parameter prediction, while system-level imprecision/bias 421 (e.g., unique to a battery type) can be addressed by a matrix correction 426 such as shown in the example of FIG. 4.

As shown in the example of FIG. 4, the chemistry reference table(s) 415 can include unique information, according to each chemistry, about the discharge profile 411, the impedance behavior 412, the one or more thermal properties 413, the imprecision and bias 414, and/or other properties. The chemistry reference table(s) 415 can provide information about variation, uncertainty, and/or confidence level unique to each chemistry in some examples. In the context of the method 200, for example, the chemistry reference table(s) 415 can be built upon analyzing the baseline data 204 from each chemistry and finding imprecision/bias 208 (e.g., the imprecision/bias 414) to generate the chemistry matrix 216 (e.g., the chemistry matrix 417).

As shown in the example of FIG. 4, a system matrix 427 in various embodiments can be obtained from a plurality of system parameters 425, including the imprecision and bias 421 from measurements, current leakage 422, and other factors 423, that are internal to the system rather than specific features, properties, or other metrics of the energy devices being measured. The system matrix 427 can be generated by or can generate the matrix correction 426 to process the plurality of system parameters 425 and train the predictive model more accurately. In the context of the method 200, for example the system matrix 218 (e.g., the system matrix 427) can be built upon analyzing the baseline data 204 from each chemistry and finding imprecision/bias 208 (e.g., the imprecision/bias 421).

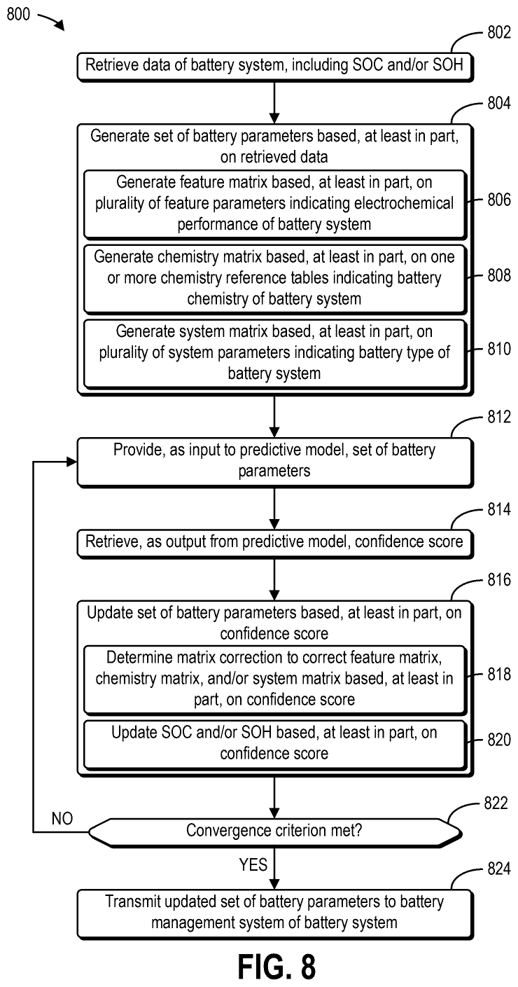

As shown in the example of FIG. 8, a predictive model can be used to monitor a battery system via a method 800. In at least one embodiment, the method 800 may be implemented by performing computer-executable instructions, stored in non-transitory memory, to cause one or more controllers, such as the one or more controllers 120 of FIG. 1, of a battery monitoring system, such as the battery monitoring system 100 of FIG. 1, to monitor a battery system, such as the battery 102 of FIG. 1. Accordingly, in certain such embodiments, the predictive model may be the predictive model 116 of FIG. 1.

At block 802, the method 800 may include retrieving data of the battery system, the retrieved data including a state-of-charge measured for the battery system and/or a state-of-health measured for the battery system. In an exemplary embodiment, the retrieved data may include one or more metrics, such as the state-of-charge and/or the state-of-health, and/or additional data indicative of operation of the battery system. For instance, the data may be retrieved, at least in part, from one or more sensors of the battery system (e.g., the sensor(s) 106 of FIG. 1). As an example, the retrieved data may include baseline data of the battery system, indicating a battery chemistry of the battery system and a battery type of the battery system. The battery chemistry may include, for example, one or more of a lithium-ion battery chemistry, an aluminum-ion battery chemistry, or a nickel metal hydride battery chemistry. As an additional or alternative example, the retrieved data may include real-time data of the battery system, indicating an electrochemical performance of the battery system.

At block 804, the method 800 may include generating (e.g., calculating, computing, or otherwise identifying) a set of battery parameters based, at least in part, on the retrieved data. In an exemplary embodiment, the set of battery parameters may include: a feature matrix, including as elements a first subset of battery parameters determined based, at least in part, on the real-time data; a chemistry matrix, including as elements a second subset of battery parameters determined based, at least in part, on a first portion of the baseline data indicating the battery chemistry; and a system matrix, including as elements a third subset of battery parameters determined based, at least in part, on a second portion of the baseline data indicating the battery type. In such an embodiment, the second subset of battery parameters may be adjusted based, at least in part, on imprecision or bias in the first portion of the baseline data, and the third subset of battery parameters may be adjusted based, at least in part, on imprecision or bias in the second portion of the baseline data.

As an example, at block 806, the method 800 may include generating a feature matrix based, at least in part, on a plurality of feature parameters indicating the electrochemical performance of the battery system. For instance, the plurality of feature parameters may indicate voltage measurements, current measurements, temperature measurements, and/or electrochemical impedance spectroscopy measurements. In an exemplary embodiment, the feature matrix may be generated at least by using principal component analysis and classification to process the plurality of feature parameters.

As an additional or alternative example, at block 808, the method 800 may include generating a chemistry matrix based, at least in part, on one or more chemistry reference tables indicating the battery chemistry of the battery system. For instance, the one or more chemistry reference tables may indicate a discharge profile, an impedance behavior, one or more thermal properties, and/or imprecision or bias unique to the battery chemistry. In an exemplary embodiment, the chemistry matrix may be generated at least by calculating, under a set of circumstances unique to the battery chemistry, a variation of the state-of-charge and/or a variation of the state-of-health to process the one or more chemistry reference tables.

As an additional or alternative example, at block 810, the method 800 may include generating a system matrix based, at least in part, on a plurality of system parameters indicating the battery type of the battery system. For instance, the plurality of system parameters may indicate imprecision or bias unique to the battery type, current leakage, and/or other factors internal to the battery cell. In an exemplary embodiment, the system matrix may be generated at least by using a matrix correction (e.g., generated at block 818 or by otherwise performing the predictive model) to process the plurality of system parameters.

At block 812, the method 800 may include providing (e.g., transmitting), as input to the predictive model, the set of battery parameters. In an exemplary embodiment, the predictive model may implement a recursive algorithm, such as a supervised recursive matrices algorithm or other trainable recursive algorithm. In such an embodiment, the recursive algorithm may iteratively generate outputs of the predictive model until a convergence criterion is met (e.g., at block 822). In some embodiments, the predictive model may be stored on, and accessed from, non-transitory memory, such as a server (e.g., server 114 of FIG. 1).

At block 814, the method 800 may include retrieving, as output from the predictive model, a confidence score (e.g., predicted by the predictive model). In an exemplary embodiment, the confidence score may correspond to an accuracy of the state-of-charge and/or an accuracy of the state-of-health.

At block 816, the method 800 may include updating the set of battery parameters based, at least in part, on the confidence score. As an example, at block 818, the method 800 may include determining a matrix correction to correct the feature matrix, the chemistry matrix, and/or the system matrix based, at least in part, on the confidence score. As an additional or alternative example, at block 820, the method 800 may include updating the state-of-charge and/or the state-of-health based, at least in part, on the confidence score.

At block 822, the method 800 may include inferring whether a convergence criterion has been met. In an exemplary embodiment, the convergence criterion may include a convergence threshold (e.g., indicating a minimum difference between the state-of-charge and the updated state-of-charge and/or a minimum difference between the state-of-health and the updated state-of-health) and/or a maximum number of iterations (e.g., of the recursive algorithm implemented by the predictive model). For instance, if it is inferred that the convergence criterion has not been met, the method 800 may include (re)providing, as input to the predictive model, the updated set of battery parameters (e.g., at block 812) so as to generate an updated confidence score (e.g., at block 814). In some embodiments, inferring that the convergence criterion has not been met may be based, at least in part, on an indication, received from the predictive model, to (further) update the set of battery parameters.

At block 824, the method 800 may include transmitting the updated set of battery parameters to a battery management system of the battery system (e.g., the battery management system 104 of FIG. 1) to adjust operation of the battery system. For instance, the updated set of battery parameters may be transmitted to the battery management system if it is inferred that the convergence criterion has been met (e.g., at block 822). In some embodiments, inferring that the convergence criterion has been met may be based, at least in part, on an indication, received from the predictive model, that the updated set of battery parameters is accurate.

In some embodiments, the method 200, the recursive algorithm 300, the method 400, and/or the method 800, or portion(s) thereof, may be implemented as executable instructions stored in non-transitory memory of a computing device, such as included in a battery monitoring system (e.g., the battery monitoring system 100 of FIG. 1). However, though the method 200, the recursive algorithm 300, the method 400, and/or the method 800 are described herein, by way of example, as an ordered sequence of steps, embodiments of methods for using a predictive model to determine SOC and/or SOH using confidence scoring are not limited to the description of the method 200, the recursive algorithm 300, the method 400, and/or the method 800. For instance, in certain embodiments, additional or alternative sequences of steps may be implemented, e.g., as executable instructions on such a computing device, and performed, where individual steps discussed with reference to the method 200, the recursive algorithm 300, the method 400, and/or the method 800 may be added, removed, substituted, modified, or interchanged.

The specification and drawings are to be regarded in an illustrative rather than a restrictive sense. It will, however, be evident that various modifications and changes may be made thereunto without departing from the broader spirit and scope of the invention as set forth in the claims. That is, the described embodiments are susceptible to various modifications and alternative forms, and specific examples thereof have been shown by way of example in the drawings and are herein described in detail.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the invention to the specific form or forms disclosed but, on the contrary, the intention is to cover all modifications, alternative constructions, and equivalents falling within the spirit and scope of the invention, as defined in the appended claims. Additionally, elements of a given embodiment should not be construed to be applicable to only that example embodiment and therefore elements of one example embodiment can be applicable to other embodiments. Additionally, in some embodiments, elements that are specifically shown in some embodiments can be explicitly absent from further embodiments. Accordingly, the recitation of an element being present in one example should be construed to support some embodiments where such an element is explicitly absent.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. Similarly, use of the term “or” is to be construed to mean “and/or” unless contradicted explicitly or by context. The terms “comprising,” “having,” “including,” and “containing” are to be construed as open-ended terms (i.e., meaning “including, but not limited to,”) unless otherwise noted. The term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. The use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but the subset and the corresponding set may be equal. The use of the phrase “based on,” unless otherwise explicitly stated or clear from context, means “based at least in part on” and is not limited to “based solely on.”

Conjunctive language, such as phrases of the form “at least one of A, B, and C,” or “at least one of A, B and C,” (i.e., the same phrase with or without the Oxford comma) unless specifically stated otherwise or otherwise clearly contradicted by context, is otherwise understood within the context as used in general to present that an item, term, etc., may be either A or B or C, any nonempty subset of the set of A and B and C, or any set not contradicted by context or otherwise excluded that contains at least one A, at least one B, or at least one C. For instance, in the illustrative example of a set having three members, the conjunctive phrases “at least one of A, B, and C” and “at least one of A, B and C” refer to any of the following sets: {A}, {B}, {C}, {A, B}, {A, C}, {B, C}, {A, B, C}, and, if not contradicted explicitly or by context, any set having {A}, {B}, and/or {C} as a subset (e.g., sets with multiple “A”). Thus, such conjunctive language is not generally intended to imply that certain embodiments require at least one of A, at least one of B and at least one of C each to be present. Similarly, phrases such as “at least one of A, B, or C” and “at least one of A, B or C” refer to the same as “at least one of A, B, and C” and “at least one of A, B and C” refer to any of the following sets: {A}, {B}, {C}, {A, B}, {A, C}, {B, C}, {A, B, C}, unless differing meaning is explicitly stated or clear from context. In addition, unless otherwise noted or contradicted by context, the term “plurality” indicates a state of being plural (e.g., “a plurality of items” indicates multiple items). The number of items in a plurality is at least two but can be more when so indicated either explicitly or by context.

Operations of processes described herein can be performed in any suitable order unless otherwise indicated herein or otherwise clearly contradicted by context. In an embodiment, a process such as those processes described herein (or variations and/or combinations thereof) is performed under the control of one or more computer systems configured with executable instructions and is implemented as code (e.g., executable instructions, one or more computer programs or one or more applications) executing collectively on one or more processors, by hardware or combinations thereof. In an embodiment, the code is stored on a computer-readable storage medium, for example, in the form of a computer program comprising a plurality of instructions executable by one or more processors. In an embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In an embodiment, code (e.g., executable code or source code) is stored on a set of one or more non-transitory computer-readable storage media having stored thereon executable instructions that, when executed (i.e., as a result of being executed) by one or more processors of a computer system, cause the computer system to perform operations described herein. The set of non-transitory computer-readable storage media, in an embodiment, comprises multiple non-transitory computer-readable storage media, and one or more of individual non-transitory storage media of the multiple non-transitory computer-readable storage media lack all of the code while the multiple non-transitory computer-readable storage media collectively store all of the code. In an embodiment, the executable instructions are executed such that different instructions are executed by different processors—for example, in an embodiment, a non-transitory computer-readable storage medium stores instructions and a main CPU executes some of the instructions while a graphics processor unit executes other instructions. In another embodiment, different components of a computer system have separate processors and different processors execute different subsets of the instructions.

Accordingly, in an embodiment, computer systems are configured to implement one or more services that singly or collectively perform operations of processes described herein, and such computer systems are configured with applicable hardware and/or software that enable the performance of the operations. Further, a computer system, in an embodiment of the present disclosure, is a single device and, in another embodiment, is a distributed computer system comprising multiple devices that operate differently such that the distributed computer system performs the operations described herein and such that a single device does not perform all operations.

Embodiments of the present disclosure can be described in view of the following clauses:
1. A method, comprising:
retrieving:
   baseline data of a battery system, indicating a battery chemistry of the battery system and a battery type of the battery system;
   real-time data of the battery system, indicating an electrochemical performance of the battery system;
   a state-of-charge, measured for the battery system; and
   a state-of-health, measured for the battery system;
identifying a set of battery parameters based, at least in part, on the baseline data and the real-time data;
providing the set of battery parameters, the state-of-charge, and the state-of-health as input to a recursive algorithm;
receiving, as output from the recursive algorithm, a first confidence score corresponding to an accuracy of the state-of-charge and an accuracy of the state-of-health;
determining one or more corrections to correct the set of battery parameters, the state-of-charge, and the state-of-health, based, at least in part, on the first confidence score; and
responsive to a convergence criterion not being met:
   providing the corrected set of battery parameters, the corrected state-of-charge, and the corrected state-of-health as input to the recursive algorithm;
   receiving, as output from the recursive algorithm, a second confidence score corresponding to an accuracy of the corrected state-of-charge and an accuracy of the corrected state-of-health; and
   updating the one or more corrections.
2. The method of clause 1, wherein the set of battery parameters is provided as input to the recursive algorithm as:
a feature matrix, including as elements a first subset of battery parameters determined based, at least in part, on the real-time data of the battery system;
a chemistry matrix, including as elements a second subset of battery parameters determined based, at least in part, on a first portion of the baseline data indicating the battery chemistry; and
a system matrix, including as elements a third subset of battery parameters determined based, at least in part, on a second portion of the baseline data indicating the battery type.
3. The method of clause 2, wherein:
the second subset of battery parameters is adjusted based, at least in part, on imprecision or bias in the first portion of the baseline data; and
the third subset of battery parameters is adjusted based, at least in part, on imprecision or bias in the second portion of the baseline data.
4. The method of any one of clauses 1-3, wherein the battery chemistry comprises one or more of a lithium-ion battery chemistry, an aluminum-ion battery chemistry, or a nickel metal hydride battery chemistry.
5. The method of any one of clauses 1-4, wherein the recursive algorithm is a supervised recursive matrices algorithm.
6. The method of any one of clauses 1-5, wherein the convergence criterion comprises one or more of a convergence threshold indicating a minimum difference between the state-of-charge and the corrected state-of-charge, a convergence threshold indicating a minimum difference between the state-of-health and the corrected state-of-health, or a maximum number of iterations of the recursive algorithm.
7. The method of any one of clauses 1-6, further comprising, responsive to the convergence criterion being met, providing the corrected state-of-charge and/or the corrected state-of-health to a battery management system of the battery system.
8. A system, comprising:
a controller; and
non-transitory memory storing executable instructions that, if performed by the controller, cause the controller to:
   receive one or more metrics comprising a measured state-of-charge of a battery cell and/or a measured state-of-health of the battery cell;
   generate a feature matrix based, at least in part, on a plurality of feature parameters indicating an electrochemical performance of the battery cell;
   generate a chemistry matrix based, at least in part, on one or more chemistry reference tables indicating a battery chemistry of the battery cell;
   generate a system matrix based, at least in part, on a plurality of system parameters indicating a battery type of the battery cell;
   predict, via a predictive model, a confidence score based, at least in part, on the one or metrics, the feature matrix, the chemistry matrix, and the system matrix;
   determine a matrix correction to correct the feature matrix, the chemistry matrix, and/or the system matrix based, at least in part, on the confidence score;
   update the one or more metrics based, at least in part, on the confidence score; and
   in response to a convergence threshold and/or a maximum number of iterations not being met:
      predict, via the predictive model, an updated confidence score based, at least in part, on the one or more updated metrics, the corrected feature matrix, the corrected chemistry matrix, and/or the corrected system matrix; and
      update the one or more metrics based, at least in part, on the updated confidence score.
9. The system of clause 8, wherein the non-transitory memory is a server further storing the predictive model.
10. The system of any one of clauses 8 or 9, wherein the executable instructions include further instructions that, if performed by the controller, cause the controller to:
transmit the one or more metrics to a battery management system of the battery cell to adjust operation of the battery cell.
11. The system of any one of clauses 8-10, wherein the predictive model comprises a trainable recursive algorithm that is to iteratively generate outputs of the predictive model until the convergence threshold and/or the maximum number of iterations are met.
12. The system of any one of clauses 8-11, wherein the executable instructions that, if performed by the controller, cause the controller to generate the feature matrix comprise instructions that, if performed by the controller, cause the controller to:
use principal component analysis and classification to process the plurality of feature parameters.
13. The system of any one of clauses 8-12, wherein the plurality of feature parameters indicate voltage measurements, current measurements, temperature measurements, and/or electrochemical impedance spectroscopy measurements.
14. The system of any one of clauses 8-13, wherein the executable instructions that, if performed by the controller, cause the controller to generate the chemistry matrix comprise instructions that, if performed by the controller, cause the controller to:
calculate, under a set of circumstances unique to the battery chemistry, a variation of the measured state-of-charge and/or a variation of the measured state-of-health to process the one or more chemistry reference tables.
15. The system of any one of clauses 8-14, wherein the one or more chemistry reference tables indicate a discharge profile, an impedance behavior, one or more thermal properties, and/or imprecision or bias unique to the battery chemistry.
16. The system of any one of clauses 8-15, wherein the executable instructions that, if performed by the controller, cause the controller to generate the system matrix comprise instructions that, if performed by the controller, cause the controller to:
use the matrix correction to process the plurality of system parameters.
17. The system of any one of clauses 8-16, wherein the plurality of system parameters indicate imprecision or bias unique to the battery type, current leakage, and/or other factors internal to the battery cell.
18. A battery monitoring system, comprising:
one or more battery cells;
one or more sensors;
a battery management system to adjust one or more operating parameters of the one or more battery cells, the battery management system communicably coupled to the one or more sensors; and
one or more controllers storing executable instructions in non-transitory memory that, if performed by the one or more controllers, are to cause the one or more controllers to:
   provide, as input to a predictive model, data from the one or more sensors;
   retrieve, as output from the predictive model:
      one or more predictions comprising a predicted state-of-charge of the one or more battery cells and/or a predicted state-of-health of the one or more battery cells; and
      a first score indicating a confidence level of the one or more predictions;
   transmit, to the predictive model, the one or more predictions and the first score;
   receive, from the predictive model, an indication to update the one or more predictions;
   retrieve, as output from the predictive model:
      one or more updates based, at least in part, on the first score, the one or more updates comprising an updated state-of-charge of the one or more battery cells and/or an updated state-of-health of the one or more battery cells;
      a second score indicating a confidence level of the one or more updates;
   transmit, to the predictive model, the one or more updates and the second score;
   receive, from the predictive model, an indication that the one or more updates are accurate; and
   transmit, to the battery management system, the one or more updates.
19. The battery monitoring system of clause 18, wherein the predictive model implements a recursive algorithm.
20. The battery monitoring system of any one of clauses 18 or 19, wherein the indication to update the one or more predictions is generated responsive to a convergence criterion not being met.

The use of any and all examples or exemplary language (e.g., “such as”) provided herein is intended merely to better illuminate embodiments of the invention and does not pose a limitation on the scope of the invention unless otherwise claimed. No language in the specification should be construed as indicating any non-claimed element as essential to the practice of the invention.

Embodiments of this disclosure are described herein, including the best mode known to the inventors for carrying out the invention. Variations of those embodiments may become apparent to those of ordinary skill in the art upon reading the foregoing description. The inventors expect skilled artisans to employ such variations as appropriate, and the inventors intend for embodiments of the present disclosure to be practiced otherwise than as specifically described herein. Accordingly, the scope of the present disclosure includes all modifications and equivalents of the subject matter recited in the claims appended hereto as permitted by applicable law. Moreover, any combination of the above-described elements in all possible variations thereof is encompassed by the scope of the present disclosure unless otherwise indicated herein or otherwise clearly contradicted by context.

All references including publications, patent applications, and patents cited herein are hereby incorporated by reference to the same extent as if each reference were individually and specifically indicated to be incorporated by reference and were set forth in its entirety herein.

1. A method, comprising:
retrieving:
baseline data of a battery system, indicating a battery chemistry of the battery system and a battery type of the battery system;
real-time data of the battery system, indicating an electrochemical performance of the battery system;
a state-of-charge, measured for the battery system; and
a state-of-health, measured for the battery system;
identifying a set of battery parameters based, at least in part, on the baseline data and the real-time data;
providing the set of battery parameters, the state-of-charge, and the state-of-health as input to a recursive algorithm;
receiving, as output from the recursive algorithm, a first confidence score corresponding to an accuracy of the state-of-charge and an accuracy of the state-of-health;
determining one or more corrections to correct the set of battery parameters, the state-of-charge, and the state-of-health, based, at least in part, on the first confidence score; and
responsive to a convergence criterion not being met:
providing the corrected set of battery parameters, the corrected state-of-charge, and the corrected state-of-health as input to the recursive algorithm;
receiving, as output from the recursive algorithm, a second confidence score corresponding to an accuracy of the corrected state-of-charge and an accuracy of the corrected state-of-health; and
updating the one or more corrections.

2. The method of claim 1, wherein the set of battery parameters is provided as input to the recursive algorithm as:
a feature matrix, including as elements a first subset of battery parameters determined based, at least in part, on the real-time data of the battery system;
a chemistry matrix, including as elements a second subset of battery parameters determined based, at least in part, on a first portion of the baseline data indicating the battery chemistry; and
a system matrix, including as elements a third subset of battery parameters determined based, at least in part, on a second portion of the baseline data indicating the battery type.

3. The method of claim 2, wherein:
the second subset of battery parameters is adjusted based, at least in part, on imprecision or bias in the first portion of the baseline data; and
the third subset of battery parameters is adjusted based, at least in part, on imprecision or bias in the second portion of the baseline data.

4. The method of claim 1, wherein the battery chemistry comprises one or more of a lithium-ion battery chemistry, an aluminum-ion battery chemistry, or a nickel metal hydride battery chemistry.

5. The method of claim 1, wherein the recursive algorithm is a supervised recursive matrices algorithm.

6. The method of claim 1, wherein the convergence criterion comprises one or more of a convergence threshold indicating a minimum difference between the state-of-charge and the corrected state-of-charge, a convergence threshold indicating a minimum difference between the state-of-health and the corrected state-of-health, or a maximum number of iterations of the recursive algorithm.

7. The method of claim 1, further comprising, responsive to the convergence criterion being met, providing the corrected state-of-charge and/or the corrected state-of-health to a battery management system of the battery system.

8. A system, comprising:
a controller; and
non-transitory memory storing executable instructions that, if performed by the controller, cause the controller to:
receive one or more metrics comprising a measured state-of-charge of a battery cell and/or a measured state-of-health of the battery cell;
generate a feature matrix based, at least in part, on a plurality of feature parameters indicating an electrochemical performance of the battery cell;
generate a chemistry matrix based, at least in part, on one or more chemistry reference tables indicating a battery chemistry of the battery cell;
generate a system matrix based, at least in part, on a plurality of system parameters indicating a battery type of the battery cell;
predict, via a predictive model, a confidence score based, at least in part, on the one or metrics, the feature matrix, the chemistry matrix, and the system matrix;
determine a matrix correction to correct the feature matrix, the chemistry matrix, and/or the system matrix based, at least in part, on the confidence score;
update the one or more metrics based, at least in part, on the confidence score; and
in response to a convergence threshold and/or a maximum number of iterations not being met:
predict, via the predictive model, an updated confidence score based, at least in part, on the one or more updated metrics, the corrected feature matrix, the corrected chemistry matrix, and/or the corrected system matrix; and
update the one or more metrics based, at least in part, on the updated confidence score.

9. The system of claim 8, wherein the non-transitory memory is a server further storing the predictive model.

10. The system of claim 8, wherein the executable instructions include further instructions that, if performed by the controller, cause the controller to:
transmit the one or more metrics to a battery management system of the battery cell to adjust operation of the battery cell.

11. The system of claim 8, wherein the predictive model comprises a trainable recursive algorithm that is to iteratively generate outputs of the predictive model until the convergence threshold and/or the maximum number of iterations are met.

12. The system of claim 8, wherein the executable instructions that, if performed by the controller, cause the controller to generate the feature matrix comprise instructions that, if performed by the controller, cause the controller to:
use principal component analysis and classification to process the plurality of feature parameters.

13. The system of claim 8, wherein the plurality of feature parameters indicate voltage measurements, current measurements, temperature measurements, and/or electrochemical impedance spectroscopy measurements.

14. The system of claim 8, wherein the executable instructions that, if performed by the controller, cause the controller to generate the chemistry matrix comprise instructions that, if performed by the controller, cause the controller to:
calculate, under a set of circumstances unique to the battery chemistry, a variation of the measured state-of-charge and/or a variation of the measured state-of-health to process the one or more chemistry reference tables.

15. The system of claim 8, wherein the one or more chemistry reference tables indicate a discharge profile, an impedance behavior, one or more thermal properties, and/or imprecision or bias unique to the battery chemistry.

16. The system of claim 8, wherein the executable instructions that, if performed by the controller, cause the controller to generate the system matrix comprise instructions that, if performed by the controller, cause the controller to:
use the matrix correction to process the plurality of system parameters.

17. The system of claim 8, wherein the plurality of system parameters indicate imprecision or bias unique to the battery type, current leakage, and/or other factors internal to the battery cell.

18. A battery monitoring system, comprising:
one or more battery cells;
one or more sensors;
a battery management system to adjust one or more operating parameters of the one or more battery cells, the battery management system communicably coupled to the one or more sensors; and
one or more controllers storing executable instructions in non-transitory memory that, if performed by the one or more controllers, are to cause the one or more controllers to:
provide, as input to a predictive model, data from the one or more sensors;
retrieve, as output from the predictive model:
one or more predictions comprising a predicted state-of-charge of the one or more battery cells and/or a predicted state-of-health of the one or more battery cells; and
a first score indicating a confidence level of the one or more predictions;
transmit, to the predictive model, the one or more predictions and the first score;
receive, from the predictive model, an indication to update the one or more predictions;
retrieve, as output from the predictive model:
one or more updates based, at least in part, on the first score, the one or more updates comprising an updated state-of-charge of the one or more battery cells and/or an updated state-of-health of the one or more battery cells;
a second score indicating a confidence level of the one or more updates;
transmit, to the predictive model, the one or more updates and the second score;
receive, from the predictive model, an indication that the one or more updates are accurate; and
transmit, to the battery management system, the one or more updates.

19. The battery monitoring system of claim 18, wherein the predictive model implements a recursive algorithm.

20. The battery monitoring system of claim 18, wherein the indication to update the one or more predictions is generated responsive to a convergence criterion not being met.
